(19) United States
(12) Patent Application Publication
(10) Pub. No.: US 2025/0306069 A1
(43) Pub. Date: Oct. 2, 2025

(54) METHOD AND APPARATUS FOR DETERMINING A TEMPORAL OFFSET BETWEEN SIGNALS AT DIFFERENT SIGNAL INPUTS

(71) Applicant: Georg-August-Universität Göttingen Stiftung Öffentlichen Rechts, Göttingen (DE)

(72) Inventors: Florentin Wörgötter, Göttingen (DE); Minja Tamosiunaite, Göttingen (DE)

(73) Assignee: Georg-August-Universität Göttingen Stiftung Öffentlichen Rechts, Göttingen (DE)

(21) Appl. No.: 19/232,731

(22) Filed: Jun. 9, 2025

Related U.S. Application Data
(63) Continuation of application No. PCT/EP2023/085073, filed on Dec. 11, 2023.

(30) Foreign Application Priority Data
Dec. 12, 2022 (DE) 10 2022 132 996.8

(51) Int. Cl. G01R 25/00

(52) U.S. Cl. CPC G01R 25/005

(57) ABSTRACT

In order to determine a temporal offset between a first signal at a first signal input and a second signal at a second signal input, a first momentary value of a first continuous signal trace, which rises strictly monotonically in a first early signal subperiod and falls strictly monotonically to zero in a first late signal subperiod and which is the first signal or is generated therefrom, is multiplied by a second momentary value of a derivative with respect to time of a second continuous signal trace, which rises strictly monotonically in a second early signal subperiod and falls strictly monotonically to zero in a second late signal subperiod and which is the second signal or generated therefrom, whereby a signal product is obtained. The signal product is integrated over time. Thus, a signal integral is obtained, which indicates the temporal offset of the first signal to the second signal.

### CROSS REFERENCE TO RELATED APPLICATIONS

This application is a continuation to international application PCT/EP2023/085073 entitled “Verfahren und Vorrichtung zur Ermittlung eines zeitlichen Versatzes zwischen Signalen an verschiedenen Signaleingängen” filed Dec. 11, 2023 and claiming priority to German patent application DE 10 2022 132 996.8 also entitled “Verfahren und Vorrichtung zur Ermittlung eines zeitlichen Versatzes zwischen Signalen an verschiedenen Signaleingängen” and filed on Dec. 12, 2022, the disclosures of which are hereby incorporated herein by reference in their entirety.

### FIELD OF THE INVENTION

The invention relates to a method and an apparatus for determining a temporal offset between signals at different signal inputs.

In many technical areas, the synchronicity of signals that are transmitted via different signal transmission lines is important. If, for example, data are transmitted in parallel over several lines at a high transmission rate, the synchronicity of the signals by which the data are transmitted over the individual lines must be significantly higher than the reciprocal of the frequency of the signals on the individual lines. Otherwise, the bits transmitted via the individual lines cannot be assigned to a specific byte or a specific other packet of data transmitted in parallel.

The same applies, if several signals are transmitted via basically the same line or signal transmission path but by means of different carrier signals that differ, for example, in terms of their frequency.

In many cases, it is not sufficient for a particular application to set the synchronicity or, more generally, the exact time sequence between different signals once, because the exact time sequence may get lost, whether due to different drifts of individual signal generators, different influences on different signal transmission paths, dispersion of the signals transmitted by means of carrier signals of different frequencies depending on environmental influences, etc.

Both for the initial setting of the exact temporal sequence and for checking and possibly readjusting the exact temporal sequence, determining the temporal offset between the respective signals as a measure of the deviation from the desired synchronization of the signals is of great interest, if not necessary, in order to be able to adjust the desired temporal sequence.

### BACKGROUND OF THE INVENTION

In order to determine a temporal offset between signals at different signal inputs, the times at which the signals arrive at the different signal inputs can be recorded and a difference between these times can be determined. For this purpose, a counter can be started at the time of arrival of the earlier of two signals and stopped at the time of arrival of the later of the two signals. The counter reading then indicates the temporal offset. The direction of the offset is indicated by which signal started the counter. Alternatively, one signal can cause the counter to count up and the other signal can cause the counter to count down, so that the sign of the counter reading indicates the direction of the temporal offset. This known method uses discrete counter time units and therefore cannot be analogized and, for this reason, it is not usable in general. Thus, it reaches its limits with small temporal offsets.

International patent application publication WO 2002/099544 A1, corresponding to U.S. patent application US 2008/0091282A1, discloses a controller for a physical apparatus which observes a correlation between different measured signals and, on this basis, automatically learns to control the apparatus. The controller comprises a first signal input for a first input signal, which indicates a measured state of the apparatus, and signal processing means which generate a control signal depending on the first input signal in order to maintain the apparatus in a desired state. The control system comprises further signal inputs for further input signals, which are additional measurements of the apparatus or its environment. The signal processing means use a weighted average of results of different fixed impulse responses to each input signal to modify the control signal, and means to automatically condition the modifications according to temporal cross-correlations observed between the further input signals and a derivative with respect to time of the control signal.

Bernd Porr and Florentin Wörgötter “Strongly Improved Stability and Faster Convergence of Temporal Sequence Learning by Using Input Correlations Only” Neural Computation, July 2006, DOI: 10.1162/neco.2006.18.6.1380 disclose a further development of the control system known from WO 2002/099544 A1. Here, instead of the temporal cross-correlations between the further input signals and the derivatives with respect to time of the control signal, temporal correlations between the derivatives with respect to time of the further input signals and the first input signal are calculated. The result obtained is used to change the amplitude of the first input signal so that it can be used as a control signal. The timing of the signals is neither determined nor changed.

U.S. Pat. No. 7,627,031 discloses an apparatus and a method for adaptively introducing a compensating signal latency which is related to a signal latency of a data symbol decision circuit. To compensate the signal latency between two signals of the data symbol decision circuit, a second input signal is delayed by a variable delay time as a function of a first latency-affected signal. The variable delay time is set by controlling a variable delay element in the form of an interpolating mixer so that the signal latency is compensated as best as possible with the delayed signal. A control variable, which is a measure of the signal latency of the decision circuit, is used to set the delay time correctly. The control variable is determined by multiplying the first signal by the derivative with respect to time of the second signal and then integrating the signal product over time.

U.S. Pat. No. 4,737,971 discloses a method and a circuit for detecting the synchronization of a first signal at a first signal input with a second signal at a second signal input. For this purpose, an asynchronous detection circuit comprises an asynchronous pulse catcher, a synchronous edge detector and an asynchronous slip detector. The asynchronous pulse catcher generates a signal whose transitions follow the transitions of a variable input frequency. The synchronous edge detector generates a single high pulse each time the signal of the asynchronous pulse catcher rises. The synchronous slip detector compares the input pulse to a reference input pulse signal at the second signal input in order to generate positive and negative slip indications. A slip processing circuit calculates a difference frequency between the input signal and the reference input signal.

U.S. Pat. No. 4,516,250 discloses a frequency and phase comparator with slip detection capability that determines a frequency difference between a reference signal of a known frequency and a variable signal of an unknown frequency. For this purpose, phase shifts of 180° and 360° between the reference signal and the variable signal are detected in the form of square-wave signals and monitored with regard to their direction. The circuitry of the frequency and phase comparator comprises a window generator, a programmable inverter, a trigger generator, a coincidence detector and a slip counter. One embodiment comprises two coincidence detectors. The first coincidence detector detects a coincidence with a positive trigger pulse; the second coincidence detector detects a coincidence with a negative trigger pulse. A coincidence that is detected by both coincidence detectors means that the leading and trailing edges of the reference signal and the variable signal match.

United States patent application publication US 2010/0231437 A1 discloses a signal processing of first and second binary signals, each containing an irregular sequence of state transitions, in a microwave obstacle detection system. A signal processing circuit comprises, in addition to a correlator, a so-called differential crosslator. Both the correlator and the differential crosslator receive a reference signal and a delayed version of the reference signal. The outputs of the correlator and the differential crosslator are forwarded to a combiner. An output signal from the combiner is the product of two functions, a correlation function and a differential crosslation function. The output signal should have an ideal shape for a high-precision delay measurement with, under ideal circumstances, a single sharp high-level positive amplitude peak without negative side peaks for each object detected by the microwave obstacle detection system.

There still is a need of a method and an apparatus for determining a temporal offset between signals at different signal inputs, which can also be implemented in analog form and are suitable for determining very small temporal offsets.

### SUMMARY OF THE INVENTION

Various embodiments relate to a method of determining a temporal offset between a first signal at a first signal input and a second signal at a second signal input. The method comprises receiving a first signal at a first signal input; providing a first continuous signal trace, which rises strictly monotonically in a first early signal subperiod and falls strictly monotonically to zero in a first late signal subperiod and which is the first signal or generated from the first signal; receiving a second signal at a second signal input; providing a derivative with respect to time of a second continuous signal trace, which strictly monotonically increases in a second early signal subperiod and strictly monotonically decreases to zero in a second late signal subperiod and which is the second signal or is generated from the second signal. The method further comprises multiplying a first momentary value of the first continuous signal trace by a second momentary value of the derivative with respect to time of the second continuous signal trace to obtain a signal product; and integrating the signal product over time to obtain a signal integral, the signal integral indicating the temporal offset of the first signal with respect to the second signal.

Various embodiments also relate to an apparatus for determining a temporal offset between a first signal at a first signal input and a second signal at a second signal input. The apparatus comprises a first signal input configured for receiving a first signal; a second signal input configured for receiving a first signal; a first pulse signal generator connected to the first signal input and configured for comparing a first signal level at the first input to a first threshold value and for recognizing a first start of the first signal by the first signal level exceeding the first threshold value; and a second pulse signal generator connected to the second signal input and configured for comparing a second signal level at the second signal input to a second threshold value and for recognizing a second start of the second signal by the second signal level exceeding the second threshold value. The apparatus further comprises an integration interval generator connected to the first and second pulse signal generators and configured for generating an integration interval after the first and second start of the earlier one of the first and second signals, the integration interval being at least as long as the first or second signal trace of the earlier one of the first and second signals; and a signal integral generator connected and configured for multiplying a first momentary value of a first continuous signal trace, which strictly monotonically increases in a first early signal subperiod and strictly monotonically decreases in a first late signal subperiod and which is the first signal or generated from the first signal, by a second momentary value of a derivative with respect to time of a second continuous signal trace, which strictly monotonically increases in a second early signal subperiod and strictly monotonically decreases in a second late signal subperiod and which is the second signal or generated from the second signal, such as to provide a signal product, and for integrating the signal product over time, such as to provide a signal integral which indicates the temporal offset of the first signal with respect to the second signal.

Other features and advantages of the present invention will become apparent to one with skill in the art upon examination of the following drawings and the detailed description. It is intended that all such additional features and advantages be included herein within the scope of the present invention, as defined by the claims.

### BRIEF DESCRIPTION OF THE DRAWINGS

The invention can be better understood with reference to the following drawings. The components of the drawings are not necessarily to scale, emphasize instead being placed upon clearly illustrating the principles of the present invention. In the drawings, like reference numerals designate corresponding parts throughout the several views.

FIG. 1 is a block diagram of a first embodiment of the method and the apparatus according to the present disclosure.

FIG. 2 shows a signal trace as it can be generated in the method according to the present disclosure.

FIG. 3 shows an embodiment example of a signal trace generator of the apparatus according to the present disclosure, which generates the signal trace as shown in FIG. 2.

FIG. 4 shows an embodiment example of an integration interval generator of the apparatus according to the present disclosure.

FIG. 5 illustrates the generation of an integration interval by the integration interval generator according to FIG. 4.

FIG. 6 illustrates the structure of a signal integral generator of the apparatus according to the present disclosure.

FIG. 7 is a plot of the signal integral obtained by the signal integral generator according to FIG. 6 over the temporal offset of a first signal with respect to a second signal.

FIG. 8 illustrates the simultaneous coupling of a laser pulse as synchronous input signals into several optical fibers of a light guide as signal transmission paths with different signal propagation times.

FIG. 9 is a block diagram of a further embodiment of the method according to the present disclosure and of the apparatus according to the present disclosure for determining the temporal offsets between output signals at the end of the signal transmission paths according to FIG. 8.

FIG. 10 illustrates a synchronization of the output signals at the outputs of the signal monitoring sections according to FIG. 8 based on the signal integrals obtained from the method and the apparatus according to the present disclosure according to FIG. 9; and

FIG. 11 shows the synchronization of ten originally asynchronous signals (left). The time course of the synchronization is shown at the bottom right. Signals are synchronous when the temporal offset has become zero. The control signals that generate the shift of the input signals to achieve the temporal offset of zero are shown at the top right.

### DETAILED DESCRIPTION

In a method for determining a temporal offset between a first signal at a first signal input and a second signal at a second signal input according to the present disclosure, a first momentary value of a first continuous signal trace, which rises strictly monotonically in a first early signal subperiod and falls strictly monotonically to zero in a first late signal subperiod, is multiplied by a second momentary value of a derivative with respect to time of a second continuous signal trace, which rises strictly monotonically to zero in a second early signal subperiod and falls strictly monotonically to zero in a second late signal subperiod, whereby a signal product is obtained. The signal product is integrated over time. Thus, a signal integral is obtained that indicates the temporal offset of the first signal to the second signal in terms of absolute value and sign.

The first signal input may be connected to a first signal transmission path and the second signal input can be connected to a separate second signal transmission path. However, the first signal input and the second signal input may also be connected to a common signal transmission path via a signal branch, for example based on the frequency of a carrier signal, i.e. via a so-called crossover.

The first continuous signal trace may be directly the first signal at the first signal input or generated from it. The first signal trace may be generated, for example, by outputting a first signal curve with a predefined signal course triggered by the arrival of the first signal at the first signal input. As a result, the signal course of the first signal trace is decoupled from the course of the first signal. The first signal may then comprise any desired course. However, if the first signal comprises a continuous signal course, rises strictly monotonically in a first early signal subperiod and falls strictly monotonically to zero in a first late signal period, the first signal itself may be used as the first continuous signal trace. The first continuous signal trace may rise strictly monotonically from zero in the first early signal subperiod and falls strictly monotonically back to zero in the first late signal period. The same applies to the second continuous signal trace. In particular, the second continuous signal trace may also be the second signal directly or be generated from it. If the second continuous signal trace is generated from the second signal in such a way that the arrival of the second signal at the second signal input triggers the output of a second signal curve with a predefined signal course, the derivative with respect to time of the second continuous signal trace can be specified directly and triggered by the arrival of the second signal at the second signal input. In any case, the derivative with respect to time of the second continuous signal trace is positive in the second early signal subperiod and initially rises until it falls again and is then negative in the second late signal period.

The signal integral obtained in the method according to the present disclosure indicates the temporal offset of interest between the first signal and the second signal in terms of absolute value and direction, namely over small temporal offsets with a linear dependence. As will be explained, the linear dependency can be set so that the signal integral indicates the temporal offset at a high resolution, i.e. with a large change in the signal integral even with small changes in the offset.

To obtain this meaningful signal integral, it is sufficient to integrate the signal product over an integration interval after the earlier of the two signals that is at least as long as the signal trace of the earlier of the two signals. Afterwards, the signal product is zero because one of its factors, i.e. the signal trace of the earlier of the two signals and thus also its derivative with respect to time, has dropped to zero.

The start or arrival of the respective signal can be detected by comparing a signal level at the respective signal input to a threshold value, whereby the point in time at which the signal level exceeds the threshold value is defined as the start or the arrival of the respective signal.

In an embodiment, the first signal curve that can be output to generate the first signal trace is a first double exponential curve, and the second signal curve that is output to generate the second signal trace is a second double exponential curve. Here, the second double exponential curve can be identical to the first double exponential curve. If, in this embodiment, the derivative of the second continuous signal trace is output directly, it is the derivative of a second double exponential curve.

In the method according to the present disclosure, the first continuous signal trace and the second continuous signal trace, regardless of whether they are the first and second signals or are generated therefrom, may be equal, i.e. may in particular comprise equal early and late signal sub-periods and equal amplitudes. However, this is not decisive for the function of the method according to the present disclosure. The signal integral obtained according to the present disclosure indicates the temporal offset of the first signal from the second signal even if the early signal sub-periods and/or the late signal sub-periods and/or the amplitudes of the signal traces are different.

In the method according to the present disclosure, the first signal trace or the derivative with respect to time of the second signal trace can be delayed by a predetermined period of time before the first momentary value of the first continuous signal trace is multiplied by the second momentary value of the derivative with respect to time of the second continuous signal trace. In this way, a desired temporal offset between the first signal and the second signal can be specified at which the signal integral becomes zero. It is irrelevant whether the first or second signal is delayed directly or only the first or second signal trace generated from it or only the derivative of the second signal trace is delayed. If a positive temporal offset between the first signal and the second signal is desired, the first signal trace must be delayed; if a negative temporal offset between the first signal and the second signal is required, the derivative of the second signal trace must be delayed.

To specifically set the desired temporal offset between the first signal at the first signal input and the second signal at the second signal input, the signal integral can be reduced to zero by acting upon a first signal transmission path to the first signal input and/or upon a first signal generator generating the first signal. In this procedure, the second signal is used as a reference to which the first signal is time-adjusted. It is understood that acting upon the first signal transmission path to the first signal input to systematically adjust the desired temporal offset of the signals is particularly effective if the first signal transmission path only transmits the first signal and does not also transmit the second signal. In principle, however, it is also possible to produce the desired temporal offset by acting upon a common signal transmission path, which also transmits the second signal, if the action upon the common signal transmission path has a different effects on signal propagation times of the two signals over the common signal transmission path.

Specifically, in the method according to the present disclosure, a first signal propagation time can be varied over the first signal transmission path by varying a first length of the first signal transmission path with the aid of a switchable delay. The switchable delay can be used to extend the first signal transmission path by different signal transmission partial paths. The signal propagation time over the first signal transmission path can also be influenced by mechanically or thermally stretching the first signal transmission path and/or by changing the temperature of a wire-based first signal transmission path.

The method according to the present disclosure can be applied to both optical and electrical signals. In both cases, the signals can be digital data signals.

The method according to the present disclosure can be used not only to determine and, if necessary, compensate for the temporal offset between the first signal and the second signal. At least one further temporal offset between a further signal at a further signal input and the second signal at the second signal input may also be determined in basically the same way as the temporal offset between the first signal at the first signal input and the second signal at the second signal input and, if necessary, compensated. On this basis, equal or different desired temporal offsets to the second signal can be set for a large number of signals. In principle, however, it is also possible to determine any further temporal offset between the further signal and a signal other than the second signal and to compensate it if necessary. In this way, too, desired temporal offsets between all signals can be set and, in particular, synchronicity of all signals can be established.

An apparatus according to the present disclosure for carrying out the method according to the present disclosure comprises the first signal input, the second signal input, a first pulse signal generator connected to the first signal input, a second pulse signal generator connected to the second signal input, an integration interval generator connected to the first pulse signal generator and the second pulse signal generator, and a signal integral generator which multiplies the first momentary value of the first continuous signal trace by the second momentary value of the derivative with respect to time of the second continuous signal trace, whereby the signal product is obtained, and which integrates the signal product over time, whereby the signal integral is obtained.

The first pulse signal generator compares the first signal level at the first signal input with the first threshold value and recognizes the start of the first signal by the fact that the first signal level exceeds the first threshold value. Accordingly, the second pulse signal generator compares the second signal level at the second signal input with the second threshold value and recognizes the second start of the second signal by the fact that the second signal level exceeds the second threshold value. The integration interval generator generates the integration interval after the start of the earlier of the two signals, the integration interval being at least as long as the earlier of the two signals. The signal integral obtained by the signal integral generator indicates the temporal offset of the first signal to the second signal in terms of absolute value and direction.

The apparatus according to the present disclosure may further comprise a first signal trace generator, which generates the first signal trace by outputting the first signal curve from the first start, and a second signal trace generator, which generates the second signal trace by outputting the second signal curve or directly its derivative with respect to time from the second start.

If the apparatus according to the present disclosure comprises an adjustable delay for the first signal trace and/or for the derivative of the second signal trace with respect to time, a desired temporal offset between the first signal and the second signal can be specified, at which the signal integral becomes zero.

Furthermore, the apparatus according to the present disclosure may comprise a time offset adjusting device which zeros the signal integral for systematically setting the desired temporal offset between the first signal and the second signal by acting upon the first signal transmission path to the first signal input and/or upon the first signal generator generating the first signal.

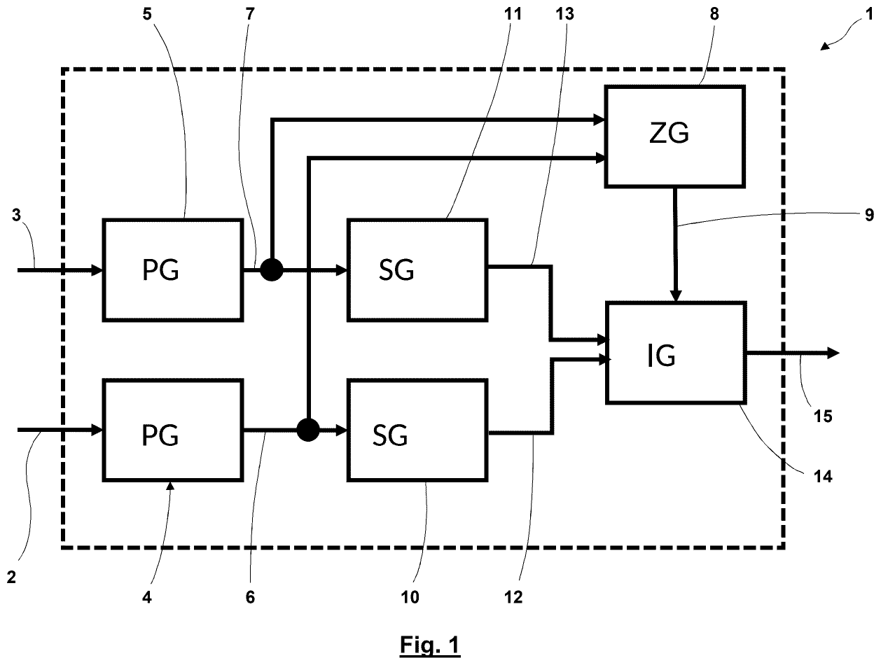

Referring now in greater detail to the drawings, the apparatus 1 illustrated in FIG. 1 comprises a first signal input 2 and a second signal input 3. A first pulse generator 4 is connected to the first signal input 2, and a second pulse generator 5 is connected to the second signal input 3. The pulse generators 4 and 5 compare a signal level present at the respective signal input 2 or 3 with a first or second threshold value and recognize the start of a first signal si arriving at the first signal input 2 and the start of a second signal so arriving at the second signal input by the fact that the respective signal level exceeds the threshold value. With the start of the respective signal s₁ Or s₀, respectively, the pulse generators 4 and 5 output a pulse signal 6 or 7 at the signal input 2 or 3, respectively, which therefore indicates the time of the start with its rising edge. Both pulse generators 4 and 5 are connected to an integration interval generator 8 on the one hand and to a first or second signal trace generator 10, 11 on the other. The integration interval generator 8 generates an integration interval 9. The signal trace generators 10 and 11 generate a first signal trace 12 and a second signal trace 13 by outputting first and second signal curves from the starts of the signals si and so, respectively. The integration interval generator 8 and the signal trace generators 10 and 11 are connected to a signal integral generator 14. The signal integral generator 14 generates a signal integral 15 from the signal traces 12 and 13 using the integration interval 9, the signal integral 15 indicating a temporal offset of the first signal si to the second signal so in terms of absolute value and direction.

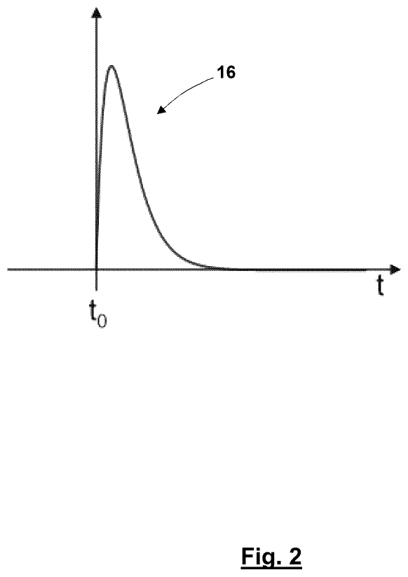

The signal traces 12 and 13 generated by the signal trace generators 10 and 11 may be double exponential curves 16, an exemplary one of which is shown in FIG. 2. From its start at a point in time t=0, the amplitude A(t) of the double exponential curves 16 is given by A(t)=exp(−at)−exp(−bt), where a is smaller than b. The double exponential curve 16 is a preferred special case of a continuous signal trace that increases strictly monotonically from zero in an early signal subperiod and decreases strictly monotonically back to zero in a late signal subperiod.

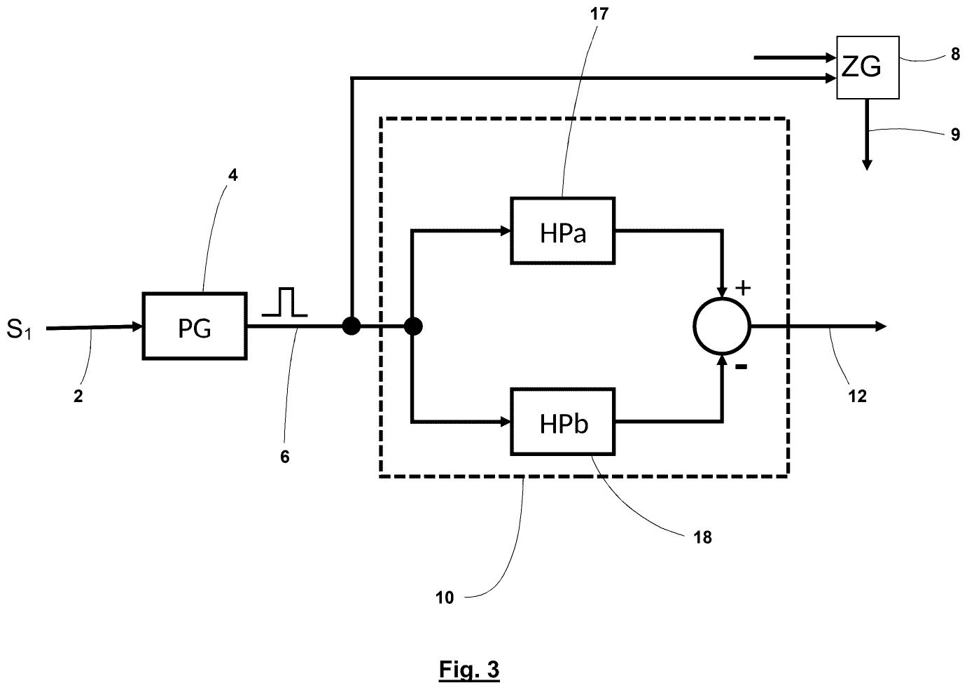

FIG. 3 illustrates a practical implementation of a signal trace generator 2 outputting a signal trace 12 in the form of a double exponential curve 16 according to FIG. 2. The signal trace generator 2 filters the pulse signal 6 coming from the pulse generator 4 as a rectangular pulse with two different high-pass filters 17 and 18. The signal trace generator 2 then subtracts the pulse signal 6 filtered with the other high-pass filter 18 from the pulse signal 6 high-pass filtered with the one high-pass filter 17 in order to generate the signal trace 12. The one high pass filter 17 generates the summand exp(−at) and the other high pass filter 18 generates the summand −exp(−bt) of the double exponential function A(t)=exp(−at)−exp(−bt).

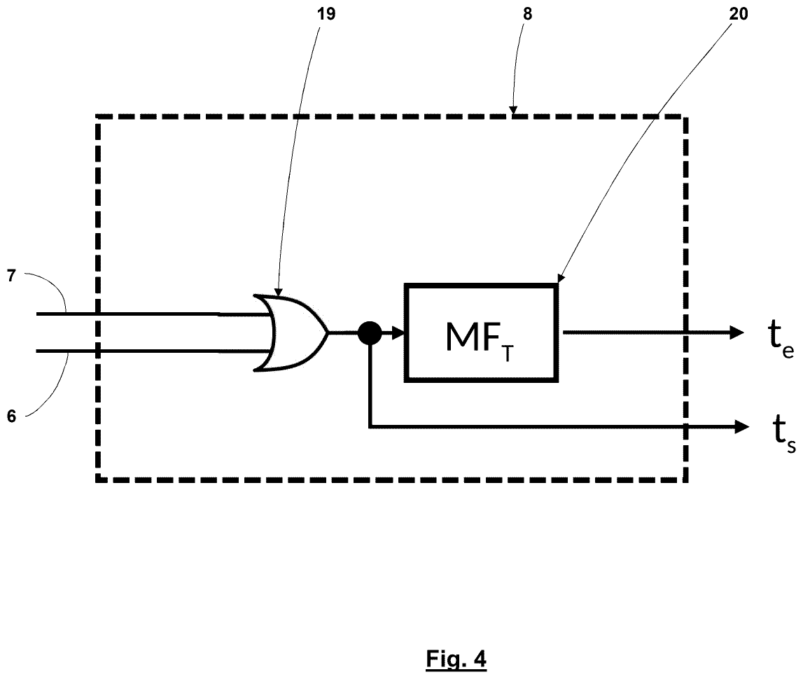

FIG. 4 illustrates an embodiment of the integration interval generator 8. An OR-gate 19 allows the earlier of the pulse signals 6 and 7 to pass through, which then triggers a retriggerable monostable trigger element 20 with the period of time D. The monostable trigger element 20 with the period of time D is triggered again by the later of the pulse signals 6 and 7.

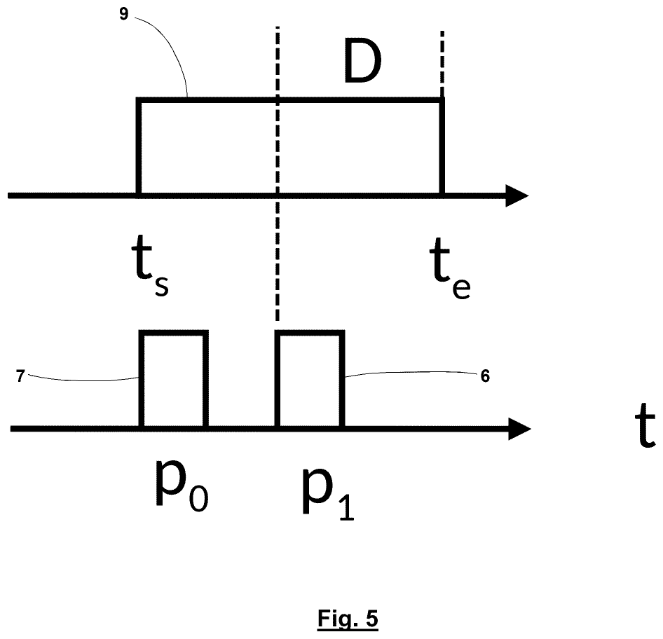

FIG. 5 shows the resulting integration interval 9 for an earlier pulse signal p₀ and a later pulse signal p₁ of the two pulse signals 6, 7 from its starting time tₛ with the rising edge of the earlier pulse signal p₀ to its end time tₑ, which is behind the rising edge of the later pulse signal p₁ by the period of time D. The left dashed line indicates the time at which the monostable trigger element is triggered again by the rising edge of the later pulse signal p₁ and then remains high for the period of time D, thus continuing the integration interval 9. The monostable trigger element can also be triggered once, i.e. only by the earlier pulse signal p₀, i.e. it does not have to be retriggerable. In any case, the selection of the period of time D must ensure that the integration interval 9 is at least as long as the signal trace 12 or 13 that is generated for the earlier pulse signal po of the two pulse signals 6, 7. Accordingly, the period of time D must be at least as long as the longer of the two signal traces 12 and 13.

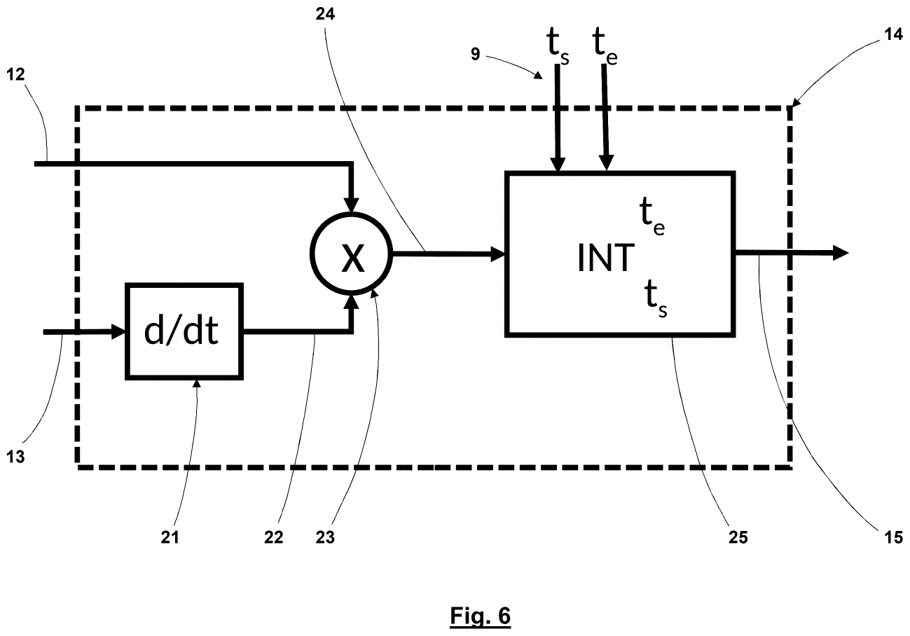

FIG. 6 shows an embodiment of the signal integral generator 14. A differentiator 21 generates a derivative 22 with respect to time of the signal trace 13 of the second signal s₀. A multiplier 23 multiplies the signal trace 12 of the first signal si at the first signal input 2 by the derivative 22, resulting in a signal product 24. An integrator 25 integrates the signal product over the integration interval 9, i.e. from tₛ to tₑ. In this way, the signal integral 15 is obtained, which indicates the offset of the signal trace 12 relative to the signal trace 13 and thus of the first signal Si at the first signal input 2 relative to the second signal so at the second signal input 3.

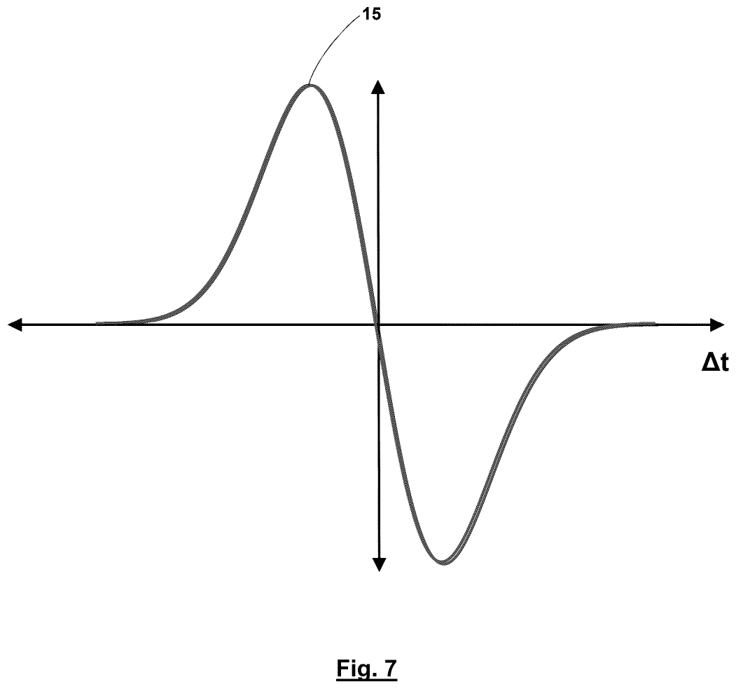

FIG. 7 is a plot of the signal integral 15 over the temporal offset Δt of the signal trace 12 or the first signal s₁ with respect to the signal trace 13 or the second signal s₀. If the signal trace 12 leads the signal trace 13, the signal integral 15 is positive because less of the signal trace 12 falls in the period in which the derivative 22 of the signal trace 13 is negative. Vice versa, the signal integral 15 is negative, if the signal trace 12 leads, because less of the signal trace 12 then falls in the time range in which the derivative 22 is positive. In between, the signal integral 15 comprises a zero crossing. At this zero crossing, the signal traces 12 and 13 and thus also the signals s₁ and s₀ at the signal inputs 2 and 3 are synchronized. Around the zero crossing, the course of the signal integral 15 is linearly dependent on the temporal offset Δt. This range of linear dependence can be varied by the periods of time of the signal sub-periods of the signal traces 12 and 13, i.e. for example the factors a and b of the summands of the double exponential curve A(t)=exp(−at)−exp(−bt). If very small temporal offsets are to be resolved, higher factors must be selected, which result in shorter early and late signal subperiods. However, larger temporal offsets Δt then lead out of the range of linear dependence of the signal integral 15 on the offset Δt or even result in a signal integral 15 outside the range shown in FIG. 7, i.e. a signal integral of zero. With smaller factors a and b, the linear range of the linear dependence of the signal integral 15 on the offset Δt is widened, but the slope in the linear range decreases, which means a lower resolution of the temporal offset Δt due to changes in the signal integral 15.

The signal integral 15 can be used to control a time offset adjusting device for systematically setting a desired temporal offset between the first signal s₁ present at the first signal input 2 and the second signal so present at the second signal input 3 and, in particular, for synchronizing the first signal s₁ with the second signal s₀. If the signal integral 15 is positive, the time offset adjusting device delays the first signal s₁ at the first signal input 2; if the signal integral 15 is negative, the time offset adjusting device ensures that the first signal s₁ is shifted forward in time at the second signal input 2. The necessary degree of delay or shifting forward of the first signal s₁ is indicated by the absolute value of the signal integral 15. When synchronizing the signals s₁ and s₀, a desired temporal offset of zero is set for the signals. In order to set a different desired temporal offset of the signals, the first signal trace 12 or the derivative 22 with respect to time of the second signal trace 13 is to be delayed by a corresponding period of time before the first momentary value of the first continuous signal trace 12 is multiplied by the second momentary value of the derivative 22 with respect to time of the second signal trace 13.

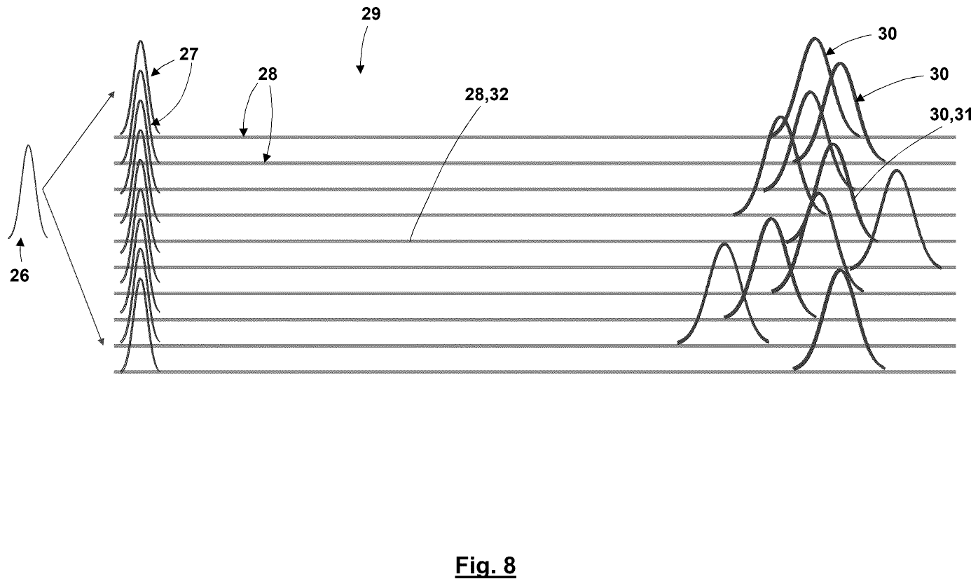

FIG. 8 illustrates coupling of a laser pulse 26 as synchronous input signals 27 into ten parallel optical fibers 28 of a light guide 29. At the other end of the light guide 29, output signals 30 emerge from the optical fibers 28, which have become temporally wider than the input signals 27 due to chromatic dispersion and which, due to manufacturing differences, different spatial routings, etc. of the individual optical fibers 28, are no longer synchronous but comprise temporal offsets. The relevant temporal offsets are of the order of a few picoseconds, for example, and can be determined and then compensated for by using the method according to the present disclosure.

Since the output pulses 30, which are still Gaussian, also qualify as signal traces that rise strictly monotonically from zero in an early signal subperiod and fall strictly monotonically back to zero in a late signal subperiod, no signal traces need to be generated to determine the offsets of the output signals 30; instead, the output signals 30 may themselves be used as signal traces 12 and 13.

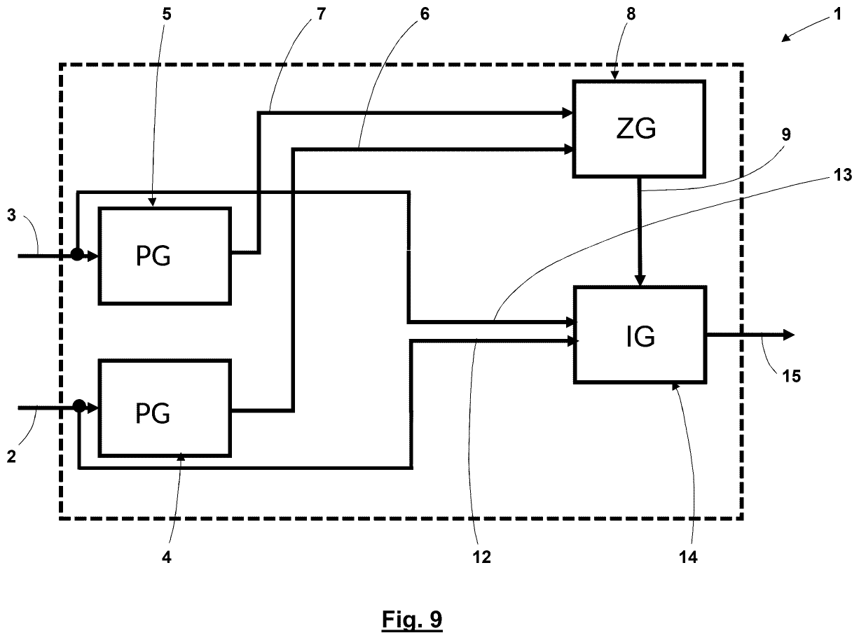

FIG. 9 shows a corresponding embodiment of the apparatus 1 without signal trace generators 10 and 11. The pulse signals 6 and 7 generated by the pulse generators 4 and 5 are only used by the integration interval generator 8 here to generate the integration interval 9. Otherwise, the first and second signals si and so applied to the signal inputs 2 and 3 are fed directly to the signal integral generator 14 as signal traces 12 and 13. Of course, this does not exclude the possibility that filters are arranged in the signal inputs 2 and 3 which only allow the relevant output signals 30 according to FIG. 8 to pass through.

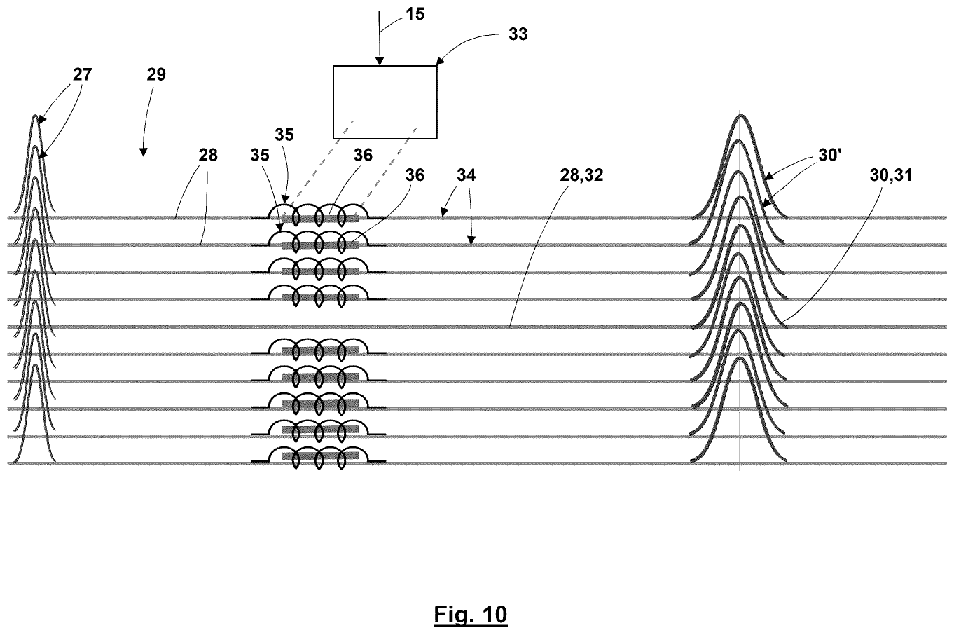

Depending on the signal integral 15, which is in each case determined for an output signal 30 emerging from one of the optical fibers 28 and an output signal 30 serving as reference signal 31 emerging from an optical fiber 28 serving as reference line 32, the time offset adjusting device 33 schematically indicated in FIG. 10 acts upon the signal transmission paths 34 embodied as the other optical fibers 28 in order to change the signal propagation times via these signal transmission paths 34 so that the synchronized output pulses 30′ shown in FIG. 10 emerge from the individual optical fibers 28. In other words, the aim of this embodiment example is to set a desired temporal offset of the signals of exactly zero, which corresponds to their synchronization.

As an intervention option of the time offset adjusting device 33 in the signal propagation time of the signal transmission paths 34, it is indicated in FIG. 10 that several 100 m of optical fiber are wound into a coil 35, the temperature of which can be changed with a thermal element 36. A temperature change of 1 degree results in a propagation time change of about 40 picoseconds per kilometer length of the wound optical fiber 28. By adjusting the temperatures of the coils 35 with the thermal elements 36, differences between the signal propagation times of the signal transmission paths 34 of a few picoseconds to several 100 picoseconds can be compensated. The signal integral 15 specifies the necessary temperature change in terms of absolute value and direction. The success of the synchronization by the time offset adjusting device 33 can be checked when the next output pulses 30 arrive at the apparatus 1 according to the present disclosure by determining the remaining temporal offsets with respect to the reference signal 31. Any remaining temporal offsets may then be compensated. If the ratio between the absolute value and direction of the signal integral 15 and the temperature change of the coils 35 caused by the time offset adjusting device 33 is optimal, the synchronization of the output pulses 30 can be achieved in one step. If the temperature changes are set slightly too small, the method converges to the synchronism of the output pulses 30 after several steps from one side. If the temperature change is too large, there is overshooting, i.e. a change in direction of the temporal offset, but if the amplification is not too large, the method still converges to the synchronism of the output pulses 30.

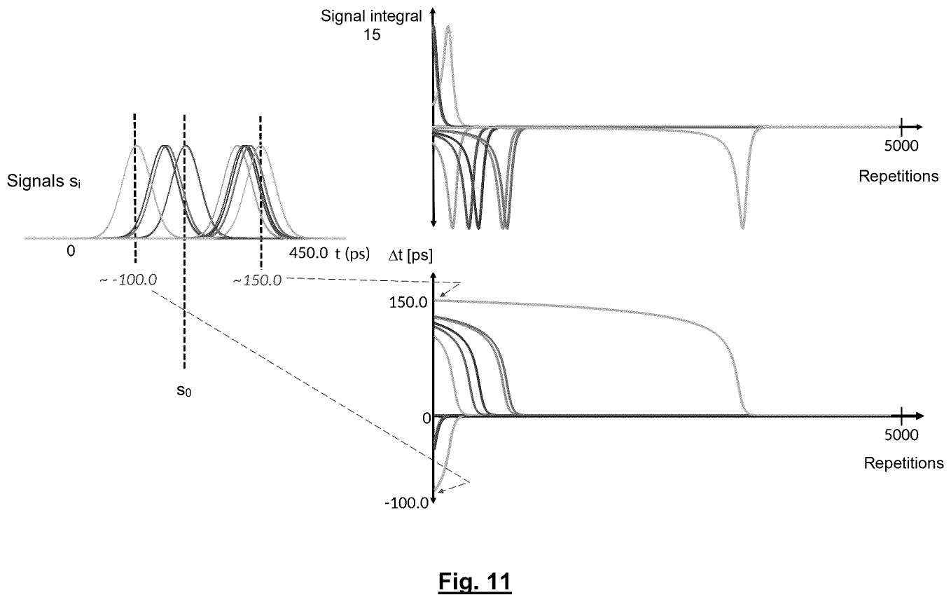

FIG. 11 shows ten time-shifted Gaussian signals sᵢ on the left, as they may occur in light guides, for example due to chromatic aberration. These signals sᵢ were fed as input signals into the method according to the present disclosure; the signal s₀, which was used as a reference for synchronization, is marked with a long-dashed line. Two other ones of the signals sᵢ, one with approx. −100 ps and another with approx. +150 ps temporal offset to the signal s₀ are highlighted with short dashed lines as examples. These ten signals sᵢ were repeated several 1,000 times and fed into the method according to the present disclosure in each case, whereby they shifted in time with respect to each other with each repetition due to the effect of the temporal offset setting with the aim of achieving an offset of zero. The time offset of the signals si is shown at the bottom right, with the zero on the y-axis corresponding to the time of the signal s₀. You can see here, for example, how the signal originally shifted at +150 ps gradually loses offset and after approx. 3,500 repetitions is synchronized with the signal s₀, i.e. a temporal offset of zero is reached. With a signal repetition rate in the range of e.g. 1 GHZ, this would correspond to a time of approx. 3.5 μs until complete synchronization. The same applies to all other signals which, however, become synchronized with the signal s₀ earlier due to their smaller original offset. Signals that are too early are delayed, so that the negative y-values are reduced, and signals that are too late are accelerated, so that the positive values are reduced. For this purpose, the signal integrals 15 generated by the method according to the present disclosure are used as control signals, see FIG. 11 top right. These control signals show the respective proportional reduction of the offset. For the signal on the far right, whose original offset was +150 ps, this results in a signal integral 15 that is initially only slightly below zero due to the small temporal overlap with the signal s₀, which then becomes increasingly negative before it rises to zero again. It can be seen that the control signal becomes zero exactly when the associated signal has become synchronous with the signal s₀.

Many variations and modifications may be made to the preferred embodiments of the invention without departing substantially from the spirit and principles of the invention. All such modifications and variations are intended to be included herein within the scope of the present invention, as defined by the following claims.

We claim:

1. A method of determining a temporal offset between a first signal at a first signal input and a second signal at a second signal input, the method comprising:
receiving a first signal at a first signal input;
providing a first continuous signal trace, which rises strictly monotonically in a first early signal subperiod and falls strictly monotonically to zero in a first late signal subperiod and which is the first signal or generated from the first signal;
receiving a second signal at a second signal input;
providing a derivative with respect to time of a second continuous signal trace, which strictly monotonically increases in a second early signal subperiod and strictly monotonically decreases to zero in a second late signal subperiod and which is the second signal or is generated from the second signal;
multiplying a first momentary value of the first continuous signal trace by a second momentary value of the derivative with respect to time of the second continuous signal trace to obtain a signal product; and
integrating the signal product over time to obtain a signal integral, the signal integral indicating the temporal offset of the first signal with respect to the second signal.

2. The method of claim 1, wherein the step of integrating comprises integrating the signal product over an integration interval after a start of an earlier one of the first and second signals, the integration interval being at least as long as the first or second signal trace of the earlier one of the first and second signals.

3. The method of claim 2, further comprising:
comparing a first signal level of the first signal to a first threshold value,
recognizing a first start of the first signal by the first signal level exceeding the first threshold value,
comparing a second signal level of the second signal to a second threshold value, and
recognizing a second start of the second signal by the second signal level exceeding the second threshold value.

4. The method of claim 3, wherein the steps of providing comprise:
generating the first signal trace from the first signal by outputting a first signal curve from the first start, and
generating the second signal trace from the second signal by outputting a second signal curve from the second start.

5. The method of claim 3, wherein the first signal curve is a first double exponential curve and the second signal curve is a second double exponential curve.

6. The method of claim 1, further comprising:
delaying the first signal trace or the derivative with respect to time of the second signal trace by a predetermined period of time before the step of multiplying the first momentary value of the first signal trace by the second momentary value of the derivative with respect to time of the second signal trace.

7. The method of claim 1, further comprising:
reducing an absolute value of the signal integral to zero by acting upon at least one of a first signal transmission path to the first signal input and a first signal generator generating the first signal for systematically setting a desired temporal offset between the first signal and the second signal.

8. The method of claim 7, wherein, in acting upon the first signal transmission, a first signal propagation time is varied over the first signal transmission path.

9. The method of claim 8, wherein, in varying the first signal propagation time, a first length of the first signal transmission path is varied.

10. The method of claim 8, wherein, in varying the first signal propagation time, a first length of the first signal transmission path is varied using a switchable delay.

11. The method of claim 1, wherein the first and second signals are selected from optical and electrical signals.

12. The method of claim 1, wherein the first and second signals are digital data signals.

13. The method of claim 1, further comprising:
determining a further temporal offset between a third signal at a third signal input and the second signal at the second signal input.

14. An apparatus for determining a temporal offset between a first signal at a first signal input and a second signal at a second signal input, the apparatus comprising:
a first signal input configured for receiving a first signal;
a second signal input configured for receiving a first signal;
a first pulse signal generator connected to the first signal input and configured for comparing a first signal level at the first input to a first threshold value and for recognizing a first start of the first signal by the first signal level exceeding the first threshold value;
a second pulse signal generator connected to the second signal input and configured for comparing a second signal level at the second signal input to a second threshold value and for recognizing a second start of the second signal by the second signal level exceeding the second threshold value;
an integration interval generator connected to the first and second pulse signal generators and configured for generating an integration interval after the first and second start of the earlier one of the first and second signals, the integration interval being at least as long as the first or second signal trace of the earlier one of the first and second signals; and
a signal integral generator connected and configured for multiplying a first momentary value of a first continuous signal trace, which strictly monotonically increases in a first early signal subperiod and strictly monotonically decreases in a first late signal subperiod and which is the first signal or generated from the first signal, by a second momentary value of a derivative with respect to time of a second continuous signal trace, which strictly monotonically increases in a second early signal subperiod and strictly monotonically decreases in a second late signal subperiod and which is the second signal or generated from the second signal, such as to provide a signal product, and for integrating the signal product over time, such as to provide a signal integral which indicates the temporal offset of the first signal with respect to the second signal.

15. The apparatus of claim 14, further comprising:
a first signal trace generator connected and configured for generating the first signal trace by outputting a first signal curve from the first start; and
a second signal trace generator connected and configured for generating the second signal trace by outputting the second signal curve or the derivative with respect to time of the second signal trace from the second start.

16. The apparatus of claim 14, further comprising:
an adjustable delay for at least one of the first signal trace and for the derivative with respect to time of the second signal trace.

17. The apparatus of claim 14, further comprising:
a time offset adjusting device connected and configured for reducing an absolute value of the signal integral to zero for systematically setting a desired temporal offset between the first and second signals by acting upon at least one of a first signal transmission path to the first signal input and a first signal generator generating the first signal.
